(19) United States
(12) Patent Application Publication
(10) Pub. No.: US 2026/0104519 A1
(43) Pub. Date: Apr. 16, 2026

(54) MONOLITHIC RETROREFLECTOR-BASED DETECTOR FOR RADIATION IMAGING

(71) Applicant: THE RESEARCH FOUNDATION FOR THE STATE UNIVERSITY OF NEW YORK, Albany, NY (US)

(72) Inventors: Paul VASKA, Miller Place, NY (US); Lemise SALEH, Coram, NY (US)

(73) Assignee: THE RESEARCH FOUNDATION FOR THE STATE UNIVERSITY OF NEW YORK, Albany, NY (US)

(21) Appl. No.: 19/115,513

(22) PCT Filed: Sep. 26, 2023
(86) PCT No.: PCT/US23/33726

§ 371 Date: Mar. 26, 2025

Related U.S. Application Data
(60) Provisional application No. 63/377,142, filed on Sep. 26, 2022.
(60) Provisional application No. 63/377,763, filed on Sep. 30, 2022.

(51) Int. Cl. G01T 1/20; H10F 39/00; H10F 39/18

(52) U.S. Cl. CPC G01T 1/20185; H10F 39/1898; H10F 39/8067

(57) ABSTRACT

An ionizing electromagnetic radiation (IEMR) detection device having a monolithic scintillator with a plurality of retroreflectors on the side of the monolithic scintillator facing the radiation source and methods of fabricating the same are provided. The detection device may be used in an imaging system. The retroreflectors are continuous with the monolithic scintillator. The monolithic scintillator produces optical photons responsive to the radiation. The plurality of retroreflectors reflects the photons back toward photodetectors which are coupled to the side opposite of the retroreflector.

### CROSS-REFERENCE TO RELATED APPLICATION

This application claims the benefit of and priority to U.S. Provisional Application Ser. No. 63/377,142 filed on Sep. 26, 2022, and U.S. Provisional Application Ser. No. 63/377,763 filed on Sep. 30, 2022 and the entirety of which are incorporated by reference.

### FIELD

This disclosure relates generally to the field of radiation imaging and, in particular, to ionizing electromagnetic radiation imaging.

### BACKGROUND

Radiation imaging such as using gamma rays or x-rays is an effective tool in the medical industry. Gamma rays may be used in imaging techniques such as positron emission tomography (PET) and single photon emission computer tomography (SPECT). PET is a powerful technique used primarily for diagnosis, treatment selection, treatment monitoring and research in cancer and neuropsychiatric disorders. Despite its high molecular specificity, quantitative nature and clinical availability, PET has not been able to achieve its full potential due in large part to its relatively poor spatial resolution compared to other imaging modalities such as CT and MRI. With this kind of spatial resolution, current devices are challenged to measure target density in small nodules and human and rodent brain regions relevant to disease etiology and pathophysiology.

Known detector systems are based on either an array of scintillator crystal modules or a monolithic scintillator. Certain systems with the array of scintillator crystal modules have an average spatial resolution of 4-5 mm. With the array of scintillator crystal modules, the size of the individual modules is directly related to the spatial resolution. This has spurred a desire and research to provide miniature scintillator crystal modules such as less than 3.0 mm. Between each module, reflectors are used to fill the space. However, as the number of modules increase and the size of each modules decreases, this causes the dead-space fraction in the array to increase. Moreover, a plurality of miniature scintillator crystal modules can be expensive and difficult to manufacture.

Monolithic scintillators are used as an alternative. However, monolithic scintillators have a wider light distribution which can lead to poor resolution. To solve this problem, some systems employ a black reflector on all surfaces other than the surface facing the photosensor array. This may reduce the spread of light but also reduces the light collection efficiency and limits the achievable energy and spatial resolution.

Other attempts to minimize light spreading (distribution) have not solved the problem. For example, certain systems have attempted to attach or couple reflectors or retroreflectors to the top of the monolithic scintillator. However, the coupling of separate elements to the top of the monolithic scintillator results in distortions and undesirable reflections due to multiple interfaces and/or materials with different indices of refraction.

### SUMMARY

Accordingly, disclosed is an ionizing electromagnetic radiation (IEMR) detection device. The device comprises an array of photodetectors and a monolithic scintillator. The monolithic scintillator has a first side and a second side. The second side is coupled to the array of photodetectors. The first side has a plurality of retroreflectors continuous with the monolithic scintillator. The plurality of retroreflectors forms a predetermined shaped pattern. The first side usually faces a source of the radiation. The monolithic scintillator is configured to produce optical photons responsive to the radiation. The plurality of retroreflectors is configured to reflect the photons back toward the photodetectors. The reflection is parallel to the incident angle for at least certain incident angles.

While typically the source of the radiation may face the first side, in an aspect of the disclosure, the source may be incident on other sides such as the photodetectors'side, a side orthogonal to the photodetector or incident at any angle with respect to the detector.

In an aspect of the disclosure, the detection device may be used for detecting x-rays or gamma rays. For example, the detection device may be used as part of an imaging system such as a positron emission tomography (PET), a single photon emission computer tomography (SPECT) and/or an x-ray imaging system.

In an aspect of the disclosure, the retroreflectors may be corner reflectors such as having a trihedral shape with 90-degree angles between each pair of the three edges. The corner reflectors reflect the photons parallel to the incident angle, for all incident angles. A retroreflector may have an edge length of about 1 mm to about 3 mm.

In an aspect of the disclosure, the detection device may further comprise an optical reflector on the retroreflector surface of at least one of the retroreflectors. In some aspects, the optical reflector may be on the surface of all of the retroreflectors. In some aspects, the optical reflector may be aluminum. In other aspects, the optical reflector may be silver, copper and/or gold or a combination thereof.

In an aspect of the disclosure, each retroreflector may be the same size. In other aspects, the size and/or shape may be based on the position of the retroreflector with respect to edges of the monolithic scintillator. In some aspects, at least two retroreflectors are at least partially aligned with a respective photodetector of the array as viewed from a direction orthogonal to the photodetector array.

Also disclosed is a method of fabricating a monolithic scintillator for an ionizing electromagnetic radiation (IEMR) detector. The method comprises forming a surface of a monolithic scintillator having a predetermined shaped pattern. The surface is on a first side of a monolithic scintillator. The predetermined shaped pattern provides a plurality of retroreflectors on the first side of the monolithic scintillator. The second side is configured to be coupled to an array of photodetection devices for the IEMR detector.

In an aspect of the disclosure, the predetermined shaped pattern may be cut into the monolithic scintillator. The method may comprise cutting the predetermined shaped pattern. In other aspects, the surface of the monolithic scintillator may be formed to have the predetermined shaped pattern by casting via a mold or three-dimensional (3D) printing. The method may comprise molding the predetermined shaped pattern or printing the predetermined shaped pattern.

In an aspect of the disclosure, grooves may be cut into the monolithic scintillator to form the predetermined shaped pattern. The method may comprise cutting the grooves. For example, in an aspect of the disclosure, a first set of grooves may be cut, and a second set of grooves may be cut. The first set of grooves may intersect the second set of grooves. In other aspects, a third set of grooves may also be cut. The third set of grooves may intersect both the first set of grooves and the second set of grooves. The retroreflectors may be formed between the grooves. The grooves may have a V-shape.

In an aspect of the disclosure, the method may further comprise coating an optical reflector on the surface of the retroreflectors.

Also disclosed is a method fabricating a detector for an ionizing electromagnetic radiation (IEMR) detector. The method comprises obtaining a monolithic scintillator having a plurality of retroreflectors on a first side, polishing a second side of the monolithic scintillator and coupling the second side of the monolithic scintillator to an array of photodetectors. The retroreflectors are formed as a predetermined shaped-pattern surface of the monolithic scintillator.

In an aspect of the disclosure, the obtained monolithic scintillator has a reflective coating on the plurality of retroreflectors. The retroreflectors may have a trihedral shape.

### BRIEF DESCRIPTION OF DRAWINGS

FIG. 1 illustrates a perspective cutaway view of an example radiation detector in accordance with aspects of the disclosure;

FIG. 2 illustrates a side cutaway view of the example radiation detector shown in FIG. 1;

FIG. 3A illustrates a perspective view of an example monolithic scintillator with integral retroreflectors in accordance with aspects of the disclosure;

FIGS. 3B and 3C illustrate side views of the example monolithic scintillator of FIG. 3A;

FIG. 3D illustrates a top view of the monolithic scintillator showing a plurality of retroreflectors in accordance with aspects of the disclosure;

FIG. 4 illustrates a perspective view of another example monolithic scintillator with integral retroreflectors in accordance with aspects of the disclosure;

FIG. 5 illustrates a wire frame view of the retroreflectors in accordance with aspects of the disclosure;

FIG. 6 illustrates an example of the detector in accordance with aspects of the disclosure showing dimensions (not to scale) used for simulation and surface comparison, and

FIGS. 7 and 8 illustrates simulation results comparing resolutions for different monolithic scintillator surfaces.

### DETAILED DESCRIPTION

In accordance with aspects of the disclosure, retroreflectors are integrated in a monolithic scintillator of an ionizing electromagnetic radiation (IEMR) detector to control the light distribution within the monolithic scintillator. This control reduces the light spreading from an event (optical photon produced within the monolithic scintillator responsive to radiation) which improves the transverse spatial resolution and depth-of-interaction (DOI) resolution and also improves other radiation detector parameters such as, but not limited to, energy deposited and time of interaction. The retroreflectors are integrated at a surface of the monolithic scintillator which typically faces the radiation source.

The term “retroreflector” used herein means a device or element (or surface) which reflects light back towards its source (parallel thereto) for at least certain angles of incidence or directions of incidence. This includes a device or element (or surface) that has this property at any angle (all angles) of incidence and all directions.

The term “integrated in” or “integrated at” or “integral” used herein means that the retroreflector(s) is/are continuous with the monolithic scintillator without any intervening physical border, optical layer, adhesive or element therebetween. In other words, the retroreflector element is formed from the scintillator itself.

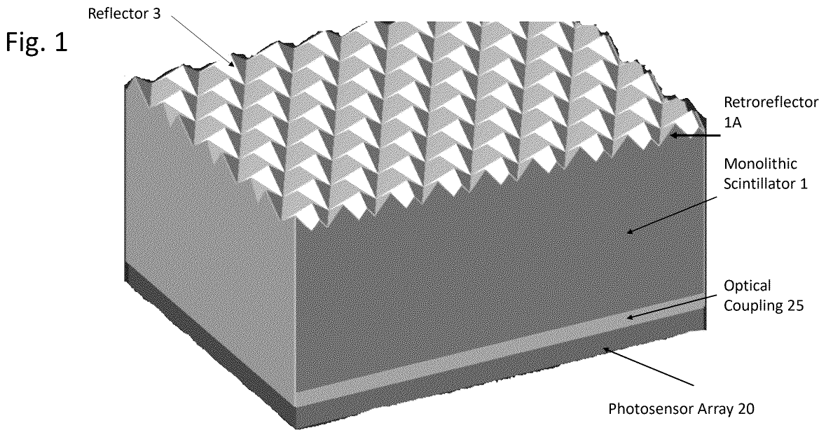

FIG. 1 illustrates a perspective cutaway view of an example detector in accordance with aspects of the disclosure. The detector may be a radiation detector such as for ionizing electromagnetic radiation (IEMR) such as gamma rays or x-rays or particles such as alpha, beta or neutrons. The detector may be used as part of an imaging system. The imaging system may include positron emission tomography (PET) and single photon emission computer tomography (SPECT).

The detector may comprise a monolithic scintillator 1 with integral retroreflectors 1A, a reflector 3, a photosensor array 20 and optical coupling 25.

In FIG. 1, each individual photosensor in the photosensor array 20 is not shown. Typically, the photosensor array 20 (optical sensors) may be manufactured in a single package or plate. Each photosensor has an active area which is spaced apart and separate from the other photosensors. The photosensor array 20 may include silicon photomultipliers (SiPM). In other aspects of the disclosure, the photosensor array 20 may include avalanche photodiodes (APDs), single-photon avalanche detectors (SPADs), photomultiplier tubes (PMTs), and silicon avalanche photodiodes (SiAPDs).

The photosensors in the array may be positioned in a two-dimensional array. The two-dimensional array is formed in a plane parallel to a side of the monolithic scintillator 1 facing the IEMR.

The monolithic scintillator 1 is configured to convert incident electromagnetic radiation into light (optical photons) which may be detected by the photosensor array 20. The monolithic scintillator 1 may be formed from crystals. For example, the monolithic scintillator 1 may be cerium-doped lutetium-yttrium oxyorthosilicate (LYSO) crystals. The monolithic scintillator is not limited to LYSO and other types of scintillators may be used that emit light photons in the presence of incident radiation, such as cerium-doped lutetium oxyorthosilicate (LSO).

The monolithic scintillator 1 may also be formed from plastic scintillators. The plastic scintillator may include a polyvinyltoluene (PVT) or a polystyrene (PSC) as the scintillator matrix and a primary fluor (dopant).

The monolithic scintillator 1 may be fabricated using three-dimensional (3D) printing or casting such as via a mold. In some aspects, the material used for 3D printing may be Yttrium aluminum garnet with cerium (YAG)(Ce). However, the material is not limited to YAG(Ce).

The monolithic scintillator 1 may be coupled to the photosensor array 20 via an optical coupling 25. As shown in FIG. 1, the monolithic scintillator 1 is coupled to the photosensor array 20 on the bottom (this is an example of the second end or second side). The optical coupling 25 may be an optical adhesive or grease to fix the position of the monolithic scintillator 1 to the array 20 and facilitate the transfer of optical photons. The specific material used for the optical coupling 25 may be based on the material used for the monolithic scintillator 1 and/or the type of photosensor to avoid additional reflections (such as based on the index of refraction). In some aspects, the material may be silicone-based.

As shown in FIG. 1, the retroreflectors 1A are provided at the top of the monolithic scintillator 1 (this is an example of the first end or first side). The example detector in FIG. 1 is a single-ended readout detector. The retroreflectors IA are positioned on the opposite end of the monolithic scintillator 1 with respect to the photosensor array 20.

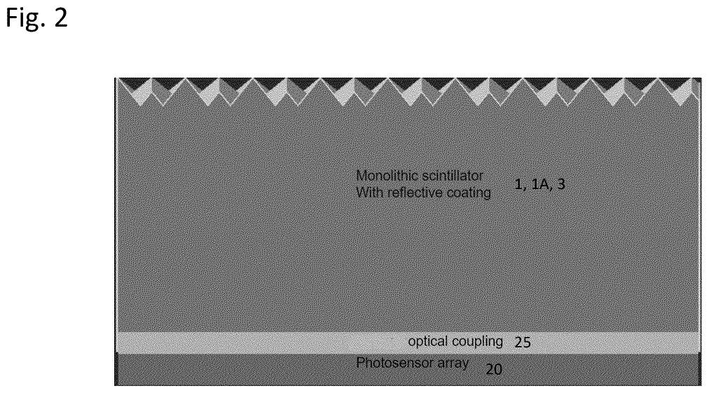

Similar to the photosensor array 20, the plurality of retroreflectors 1A may be arranged in a two-dimensional pattern (predetermined shaped pattern) at the first side of the monolithic scintillator 1 such as shown in FIG. 1. This pattern is also shown in FIG. 2 which is an end view. While in FIG. 2, the retroreflectors 1A may appear to have different heights given the perspective of the figure, in some aspects, the retroreflectors 1A may have the same heights.

The dimensions of the retroreflectors and/or shapes may be based on the type of imaging system, the height of the monolithic scintillator 1, the size of each photosensor (including pitch and/or active area) and measurement performance needed such as transverse location and/or DOI.

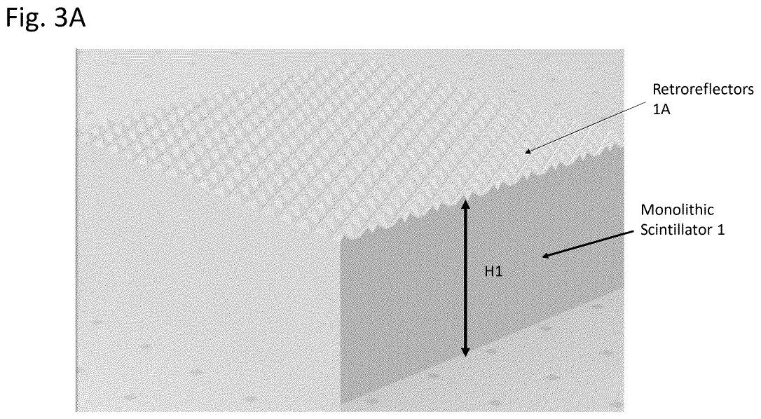

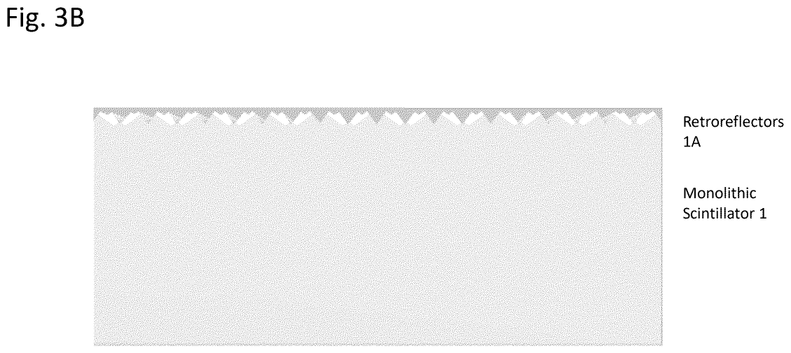

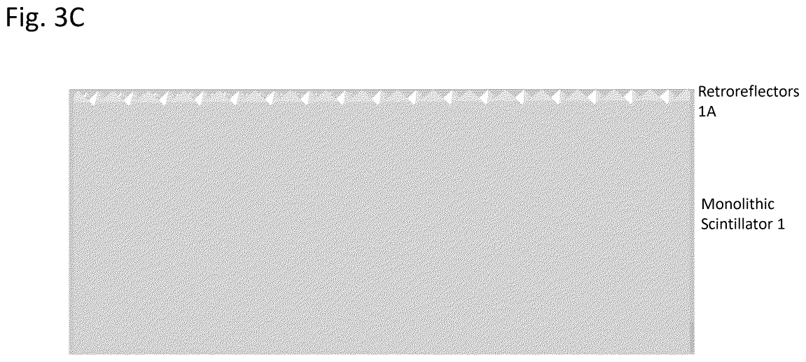

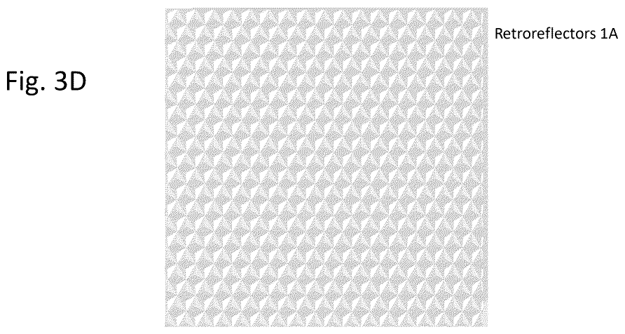

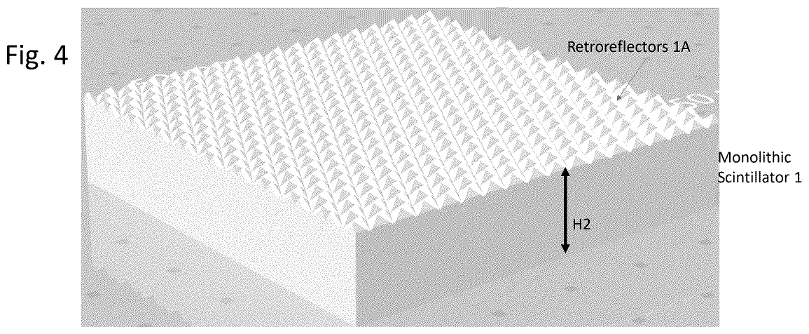

FIG. 3A illustrates an example monolithic scintillator 1 in accordance with aspects of the disclosure. This monolithic scintillator 1 has a height of H1. In an aspect of the disclosure, this height may be 20 mm. However, the height of the monolithic scintillator 1 may be other heights based on the application and size of the system. For example, in other aspects, the monolithic scintillator 1 may have a height H2, e.g., 10 mm, such as shown in FIG. 4. The height of the monolithic scintillator 1 referenced herein means the distance from the bottom of the scintillator layer to where the base 600 of the retroreflector 1A is.

The monolithic scintillator 1 may have the same x and y dimension. Given the dimensions of the monolithic scintillator 1, at the edges of the monolithic scintillator 1, the retroreflectors 1A may be truncated (e.g., have a different shape from the others) such as shown in FIGS. 3A and 3D. FIG. 3B illustrates end view of the retroreflectors 1A/monolithic scintillator 1 from a first end and FIG. 3C illustrates an end view of the retroreflectors 1A/monolithic scintillator 1 from a second end. The second end is orthogonal from the first end. The end views also show the truncation at the edges.

In some aspects of the disclosure, the retroreflectors 1A may be corner reflectors which have a trihedral shape with 90-degree angles between edges at the vertex such as shown in the figures. The corner reflector may also be referred to herein as integrated corner reflector (ICR). The corner reflector shape allows for the retro reflectance to be symmetric. In other words, no matter the direction of the source of the photon or incidence angle, the corner reflector shape reflects the light back toward the source and parallel thereto.

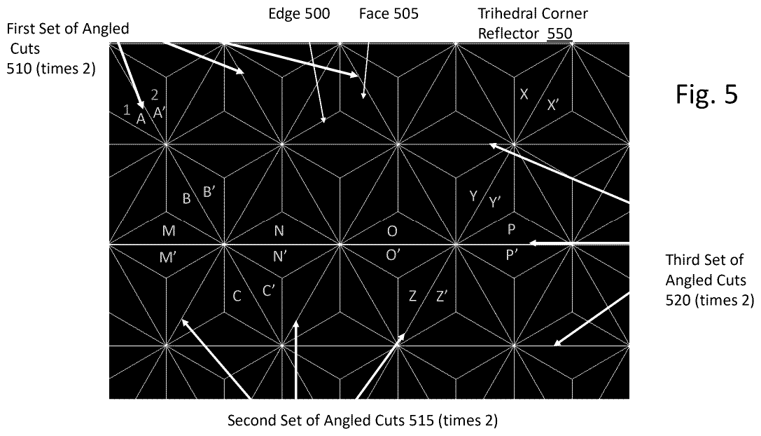

FIG. 5 illustrates an example of a trihedral corner reflector 550 in accordance with aspects of the disclosure, the trihedral corner reflector 550 has three faces 505 extending from a base. Adjacent faces are connected by an edge 500. The edge 500 extends from the base 600 to the apex or tip of the trihedral corner reflector 550.

The length of an edge 500 (and thus the height of the trihedral corner reflector 550) may be based on imaging system, the height of the monolithic scintillator 1, the size of the photosensor and measurement(s) needed, such as transverse location and/or DOI such as described above. Since the retroreflectors 1A reflects light back towards the photon source and limits the spreading (e.g., confines the light), the smaller the edge (and thus the height) may reduce the spreading better than a larger edge. Larger edges may also cause non-uniformity in the response at different depths whereas smaller edges may provide more uniform responses.

Given the symmetry of the trihedral corner reflector 550, the limits to the spreading should be relatively symmetric in the x and y directions.

In some aspects of the disclosure, the length of an edge 500 may be about 0.1 mm to about 9 mm. In other aspects of the disclosure, the length of an edge 500 may be about 1 mm to about 9 mm. In other aspects of the disclosure, the length of an edge 500 may be about 1 mm to about 3 mm. In other aspects of the disclosure, the length of an edge 500 may be about 3 mm. In some aspects, depending on the size of the retroreflector, more than one retroreflector may be aligned (or partially aligned), as viewed from a direction orthogonal to the photosensor array, with a given photosensor of the photosensor array 20.

In an aspect of the disclosure, the monolithic scintillator 1 with retroreflectors 1A may be made via a series of cuts on the first side of the monolithic scintillator 1. The series of cuts may be made using one or more blades. In other aspects, the series of cuts may be made using one or more lasers or other mechanical means. The one or more blades or one or more lasers under the control of one or more processors is an example of a cutting unit.

For example, on the “top” surface of the monolithic scintillator 1 (the side of the monolithic scintillator, which in operation or may face the radiation source), a first set of angled cuts 510 may be made at first preset angles. The orientation of the monolithic scintillator 1 may depend on the position of the detector. For example, when the detector is above a patient being imaging, the “top” surface may be on the “bottom” facing the patient and where the detector is on the side of the patient, the “top” surface” may be on a side facing the patient. In other aspects, the radiation source may be incident on other surface(s) of the detector such as the photodetector surface or surface(s) orthogonal to the photodetector surface (side of the monolithic scintillator 1). The pair of cuts may be offset by a specified distance based on the size of the base 600 of the retroreflector. The specified distance may be uniform. In other aspects when the size of the reflectors are different, the specified distance may be different between adjacent pairs of cuts. When multiple blades or lasers are used, each cut of the same angle may be made simultaneously. In other aspects, when one blade or laser is used, the cuts may be sequentially made where a cut is made followed by movement of the monolithic scintillator 1 or the machine with the cutting unit. The first set of angled cuts 510 are shown in FIG. 5. A pair of cuts are made to create a groove. In some aspects of the disclosure, the angle of the cuts may be about +/−35°from the normal to a scintillator surface, forming a V-shaped groove with angle of about 70 degrees. The pairs are labeled as (times 2) in FIG. 5. For example, the angle may be +/−35.27°. Each cut makes an angled slot in the monolithic scintillator 1. As shown in FIG. 5, the one of the angled cuts (of the first set of angled cuts) makes slot identified as “1”. The other of the angled cuts (for the first set of angled cuts) is identified as “2”. The angled cut makes a respective face of a retroreflector. Thus, the groove makes faces of adjacent retroreflectors. For example, as shown in FIG. 5, the angled cut which makes slot 1 creates the face for different retroreflectors (identified in FIG. 5 as A, B and C). Similarly, the cut for slot 2 makes the face for different retroflectors (identified in FIG. 5 as A′, B′, C′). The cut for slot 1 may be followed for the cut for slot 2. This may be repeated for the adjacent angled cut lines. Alternatively, all of the slots 1 may be made followed by all of the slot 2 (or vice versa).

After the first set of angled cuts 510 are made, the monolithic scintillator 1 or the cutting unit may be rotated by a set amount to make the second set of angled cuts 515. In an aspect of the disclosure, the rotation may be about 60°. Once the rotation is completed, the second set of angled cuts 515 may be made using the cutting unit such as shown in FIG. 5. Similar to above, two cuts may be made to create a respective groove. The pairs are labeled as (times 2) in FIG. 5. The pairs of the cuts may offset by the specified distance based on the size of the base 600 of the retroreflector. The specified distance may be uniform. In other aspects when the size of the reflectors is different, the specified distance may be different between adjacent pairs of cuts. In some aspects, the angle of each cut for the second set of angled cuts 515 may be the same as the first preset angles (second preset angles equal to the first preset angles). In some aspects of the disclosure, the angle of the pair of cuts (to form a V-shaped groove) may be about +/−35° from the normal to the scintillator surface. For example, the angle may be +/−35.27°. However, the disclosure is not limited to the angles being equal. Once again, the V-shaped groove may have an angle of about 70 degrees. For example, one cut may make the face for the different retroreflectors (identified as X, Y and Z) and one cut may make the face for the adjacent retroreflectors X′, Y′ and Z′, respectively).

After the second set of angled cuts are made, the monolithic scintillator 1 or the cutting unit may be rotated by a set amount to make the third set of angled cuts 520. In an aspect of the disclosure, the rotation may be about 60°. Once the rotation is completed, the third set of angled cuts 520 may be made using the cutting unit which are shown in FIG. 5. Similar to above, two cuts may be made to create a respective groove. The pairs are labeled as (times 2) in FIG. 5. The pairs of cuts may also be offset by the specified distance based on the size of the base 600 of the retroreflector. The specified distance may be uniform. In other aspects when the size of the reflectors is different, the specified distance may be different between adjacent pairs of cuts. In some aspects, the angles of the cuts may be the same as the first preset angles or the second preset angles (third preset angles equal to the first preset angles). Once again, the V-shaped groove may have an angle of about 70 degrees. For example, one cut may make the face for the different retroreflectors (identified as M, N, O and P) and one cut may make the face for the adjacent retroreflectors M′, N′, O′ and P′, respectively).

The order of the cuts may be different than as described such as the third set of angled cuts 520 may be made first following by the first set of angled cuts 510 or the second set of angled cuts 515.

In some aspects of the disclosure, a reflector 3 may be deposited on the exposed surface of at least some of the retroreflectors. In some aspects, the reflective material for the reflector 3 may be sputtered on the surface. However, in other aspects, the reflective material may be coated or painted onto the surface. The reflective material may be aluminum, silver, copper, gold, etc. or a combination thereof. The thickness of the reflector 3 may be based on the size of the retroreflector and application. In some aspects, the thickness may be nanometers such as 500 nm to 1600 nm.

Due to the nature of the cutting, such that the intersection of the first set of cuts and the second set of cuts, a portion of the monolithic scintillator 1 may not have a retroreflector 1A because the material is cut off (two side edges).

In FIG. 5, the intersections of the first, second and third set of angled cuts are highlighted (corner of each retroreflector 1A) (i.e., intersection of the grooves).

In some aspects, the bottom of the monolithic scintillator 1 may be polished for coupling to the photosensor array 20.

In other aspects of the disclosure, instead of cutting the monolithic scintillator 1 to form the retroreflectors 1A, the monolithic scintillator 1 and integrated retroreflectors 1A may be fabricated using 3D printing techniques. Advantageously, by using 3D printing, the size and shape of the retroreflector(s) 1A and subsequently the reflector 3 may be controlled on a micrometers scale, enabling the retroreflectors 1A to be fabricated to be small, as targeted, without any limitations due to machining and cutting.

In other aspects, the monolithic scintillator 1 with integrated retroflectors 1A may be fabricated using a mold. For example, the mold may have a predetermined pattern formed for the retroreflectors IA on one side and the scintillating material (such as a scintillating plastic) is poured into the mold to form the monolithic scintillator 1 with integrated retroflector 1A

The shape of a retroreflector 1A is not limited to trihedral, and other retroreflective shapes may be used. For example, the retroreflectors 1A may have a dihedral shape, e.g., upside down “V” shape such as a right-angle prism. The right-angle prism may have a length greater than the width. In this regard, the retro reflective property may be in the x or y direction. In this aspect of the disclosure, an array of retroreflectors 1A may be formed by alternating the orientation of the right-angle prism such that the longer side alternates with a shorter side of an adjacent right-angle prism.

The retroreflectors 1A may also have different prismatic shapes which have retroreflective properties at various incidence angles including 4-sided pyramids (or truncated thereof), wedges, cupolae, cones, frusta, etc.

In an aspect of the disclosure, the size and shape of the retroreflectors IA in the array may be different depending on the location of the retroreflector 1A in the array. For example, retroreflectors 1A near the edge of the monolithic scintillator 1 may be smaller than the retroreflectors 1A in the center of the monolithic scintillator 1. This may increase the resolution and improve the light scattering near the edge of the monolithic scintillator 1. Also, by having smaller retroreflectors near the edge, the retroreflectors 1A may not need to be truncated.

A detector for a radiation imaging system may be formed by obtaining the monolithic scintillator 1. The monolithic scintillator 1 may already have prefabricated retroreflectors 1A on the first side. The retroreflectors 1A may be fabricated as described above (cutting unit, 3D printing or casting). Additionally, in some aspects, the monolithic scintillator 1 may already have prefabricated reflector 3 on the retroreflector 1A. In other aspects, both the retroreflectors 1 and reflector 3 may need to be fabricated as described herein.

The exposed surface of the reflector 3 and/or the exposed surface (bottom) of the monolithic scintillator 1 may need to be polished such as to provide a smooth surface for coupling to the photosensor array 20. Once polished as needed, the monolithic scintillator 1 (with the integrated retroreflectors 1A and reflector 3) may be attached to the photosensor array 20 via the optical coupling 25.

The structure may be electrically connected to a readout integrated circuit (ROIC). The ROIC may be coupled to a processor and a memory for determining the position of the event such as the transverse position and/or DOI. The memory stores the read out information, the determined transverse position and/or DOI. The processor may determine the transverse position and/or DOI using computer-readable instructions stored in the memory. In an aspect of the disclosure, each individual photosensor in the array may be separately read out.

### Simulation

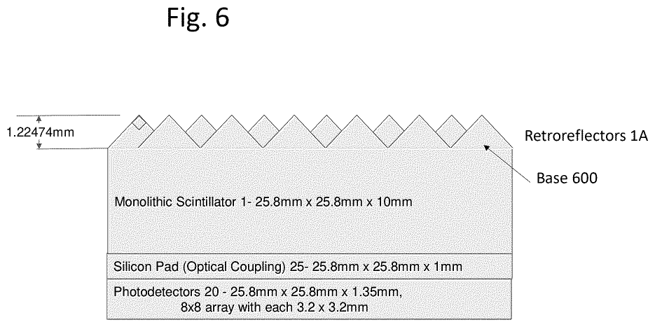

The performance of the detector with integrated corner reflectors (ICRs) in accordance with aspects of the disclosure was compared with other entrance surface configurations using simulations. FIG. 6 illustrates an example of the parameters of one of the detectors with ICRs in accordance with aspects of the disclosure. The monolithic scintillator 1 has a height of 10 mm and an x and y dimension of 25.8 mm×25.8 mm. The x and y dimension was the same as the photosensor array. The photosensor array was simulated as a Hamamatsu S14161-3050HS-08, which is a 8×8 sensor array. Each sensor was simulated to have an active area of about 3×3 mm with a pitch (spacing) of approximately 3.2 mm (providing a gap between respective active areas). The simulation used a silicon pad as the optical coupling 25 (1 mm thick and same x and y dimensions as the monolithic scintillator and photosensor array).

Trihedral corner retroreflectors were used. For the stimulation two different edge lengths were used: 1 mm and 3 mm. FIG. 6 illustrates the 3 mm edge (1.22474 mm height). The base 600 of the reflectors 1A is shown using a white line, however, as described herein, there is no physical border or interface between the monolithic scintillator 1 and the retroreflectors 1A.

For the comparison in the different entrance face finishes a fully absorptive black paint was simulated and a flat polished specular reflector (polished and bonded with enhanced specular reflector (ESR) was simulated. The simulation was done in GATE, which is a Monte Carlo toolkit. The monolithic scintillator 1 was modeled as LYSO. Photon interaction at the surfaces were simulated with the Davis LUT model, which is a validated model of crystal reflectance based on measurement of 3D crystal surfaces.

A representative photon detection efficiency (PDE) of the photosensor array (Hamamatsu) was used, e.g., 40% and electronic readout noise was included. A simulated point source of 511 keV gamma-rays was also used.

The intrinsic transverse resolution was measurement by moving a perpendicular beam of gamma-rays in set increments across the center-most SiPM of the photosensor array. The simulated true radiation source position was compared with the calculated position using the photosensors.

Anger Logic and local slope was used to convert the calculated position centroid from bins to mm (full-width at half max or FWHM). To analyze the DOI, a radiation source was simulated to be at the center of an SiPM.

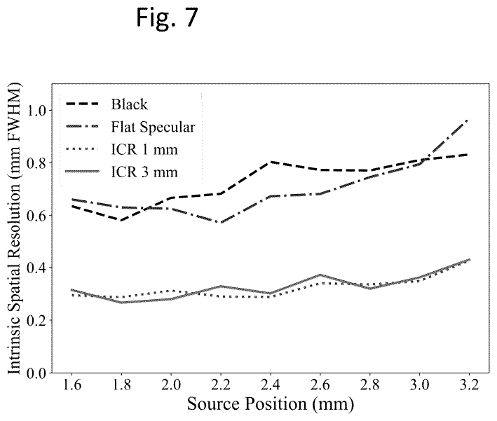

FIG. 7 illustrates the intrinsic transverse spatial resolution of the various detectors described above from the simulation. 1.6 on the x-axis is the center of the center SiPM and 3.2 mm is the edge of the center SiPM in the array. As can be seen, the use of the ICR (both 1 mm and 3 mm edge) greatly improves the transverse spatial resolution, by approximately a factor of 2, from ˜0.8 mm FWHM to ˜0.4 mm FWHM. There is a small difference between the transverse spatial resolution for the 1 mm and 3 mm ICR.

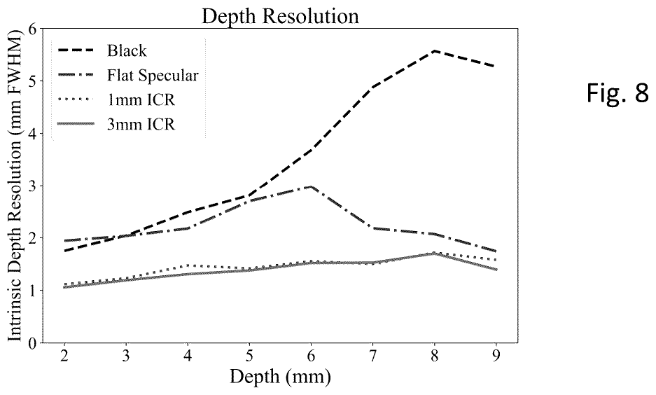

FIG. 8 illustrates the intrinsic DOI resolution of the various detectors described above from the simulation. 0 on the x axis is at the base 600 of the retroreflector and 10 is at the interface between the monolithic scintillator and the photosensor. Depth resolution for the ICR designs are generally <2 mm FWHM, whereas the black and flat specular designs are >2 mm, reaching 3-5 mm FWHM at some depths. DOI position was calculated based on the variance of the light spread function (LSF) width at each depth.

In the discussion and claims herein, the term “about” indicates that the value listed may be somewhat altered, as long as the alteration does not result in nonconformance of the process or device. For example, for some elements the term “about” can refer to a variation of ±0.1%, for other elements, the term “about” can refer to a variation of ±1% or ±10%, or any point therein. For example, the term about when used for a measurement in mm, may include +/0.1, 0.2, 0.3, etc., where the difference between the stated number may be larger when the state number is larger. For example, about 1.5 may include 1.2-1.8, where about 20, may include 19.0-21.0.

As used herein, the term “substantially”, or “substantial”, is equally applicable when used in a negative connotation to refer to the complete or near complete lack of an action, characteristic, property, state, structure, item, or result. For example, a surface that is “substantially” flat would either completely flat, or so nearly flat that the effect would be the same as if it were completely flat. “Substantially” when referring to a shape or size may account for manufacturing where a perfect shapes, such as circular or sizes may be difficult to manufacture.

As used herein terms such as “a”, “an” and “the” are not intended to refer to only a singular entity, but include the general class of which a specific example may be used for illustration. As used herein, terms defined in the singular are intended to include those terms defined in the plural and vice versa.

References in the specification to “one aspect”, “certain aspects”, “some aspects” or “an aspect”, indicate that the aspect(s) described may include a particular feature or characteristic, but every aspect may not necessarily include the particular feature, structure, or characteristic. Moreover, such phrases are not necessarily referring to the same aspect. Further, when a particular feature, structure, or characteristic is described in connection with an aspect, it is submitted that it is within the knowledge of one skilled in the art to affect such feature, structure, or characteristic in connection with other aspects whether or not explicitly described. For purposes of the description hereinafter, the terms “upper”, “lower”, “right”, “left”, “vertical”, “horizontal”, “top”, “bottom”, and derivatives thereof shall relate to a device relative to a floor and/or as it is oriented in the figures.

Reference herein to any numerical range expressly includes each numerical value (including fractional numbers and whole numbers) encompassed by that range. To illustrate, reference herein to a range of “at least 50” or “at least about 50” includes whole numbers of 50, 51, 52, 53, 54, 55, 56, 57, 58, 59, 60, etc., and fractional numbers 50.1, 50.2 50.3, 50.4, 50.5, 50.6, 50.7, 50.8, 50.9, etc. In a further illustration, reference herein to a range of “less than 50” or “less than about 50” includes whole numbers 49, 48, 47, 46, 45, 44, 43, 42, 41, 40, etc., and fractional numbers 49.9, 49.8, 49.7, 49.6, 49.5, 49.4, 49.3, 49.2, 49.1, 49.0, etc.

As used herein, the term “processor” may include a single core processor, a multi-core processor, multiple processors located in a single device, or multiple processors in wired or wireless communication with each other and distributed over a network of devices, the Internet, or the cloud. Accordingly, as used herein, functions, features or instructions performed or configured to be performed by a “processor”, may include the performance of the functions, features or instructions by a single core processor, may include performance of the functions, features or instructions collectively or collaboratively by multiple cores of a multi-core processor, or may include performance of the functions, features or instructions collectively or collaboratively by multiple processors, where each processor or core is not required to perform every function, feature or instruction individually. For example, a single FPGA may be used or multiple FPGAs may be used to achieve the functions, features or instructions described herein. For example, multiple processors may allow load balancing. In a further example, a server (also known as remote, or cloud) processor may accomplish some or all functionality on behalf of a client processor.

As used herein, the term “processor” or the term “controller” may be replaced with the term “circuit” such as an ASIC. The term “processor” may refer to, be part of, or include processor hardware (shared, dedicated, or group) that executes code and memory hardware (shared, dedicated, or group) that stores code executed by the processor.

Further, in some aspect of the disclosure, a non-transitory computer-readable storage medium comprising electronically readable control information stored thereon, configured in such that when the storage medium is used in a processor, aspects of the functionality described herein is carried out.

Even further, any of the aforementioned methods may be embodied in the form of a program. The program may be stored on a non-transitory computer readable medium and is adapted to perform any one of the aforementioned methods when run on a computer device (a device including a processor). Thus, the non-transitory, tangible computer readable medium, is adapted to store information and is adapted to interact with a data processing facility or computer device to execute the program of any of the above mentioned embodiments and/or to perform the method of any of the above mentioned embodiments.

The computer readable medium or storage medium may be a built-in medium installed inside a computer device main body or a removable medium arranged so that it can be separated from the computer device main body. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The term memory hardware is a subset of the term computer-readable medium.

The described aspects and examples of the present disclosure are intended to be illustrative rather than restrictive, and are not intended to represent every aspect or example of the present disclosure. While the fundamental novel features of the disclosure as applied to various specific aspects thereof have been shown, described and pointed out, it will also be understood that various omissions, substitutions and changes in the form and details of the devices illustrated and in their operation, may be made by those skilled in the art without departing from the spirit of the disclosure. For example, it is expressly intended that all combinations of those elements and/or method steps which perform substantially the same function in substantially the same way to achieve the same results are within the scope of the disclosure. Moreover, it should be recognized that structures and/or elements and/or method steps shown and/or described in connection with any disclosed form or aspects of the disclosure may be incorporated in any other disclosed or described or suggested form or aspects as a general matter of design choice. Further, various modifications and variations can be made without departing from the spirit or scope of the disclosure as set forth in the following claims both literally and in equivalents recognized in law.

What is claimed is:

1. An ionizing electromagnetic radiation (IEMR) detection device comprising:
an array of photodetectors; and
a monolithic scintillator having a first side and a second side, the second side being coupled to the array of photodetectors, the first side having a plurality of retroreflectors continuous with and composed of a same material as the monolithic scintillator, the plurality of retroreflectors forms a predetermined shaped pattern the monolithic scintillator configured to produce optical photons responsive to the radiation, wherein the plurality of retroreflectors being configured to reflect the photons back toward the photodetectors, wherein at least for certain incident angles the reflection being parallel to the incident angle.

2. The IEMR detection device of claim 1, wherein for all incident angles, the plurality of retroreflectors reflects the photon parallel to the incident angle.

3. The IEMR detection device of claim 2, wherein the retroreflectors have a trihedral shape.

4. The IEMR detection device of claim 3, wherein the trihedral has an edge length of about 1 mm to about 3 mm.

5. The IEMR detection device of claim 1, further comprising an optical reflector on the retroreflector surface.

6. The IEMR detection device of claim 5, wherein the optical reflector is aluminum.

7. The IEMR detection device of claim 1, wherein the plurality of retroreflectors has a same size.

8. The IEMR detection device of claim 1, wherein a size of the retroreflector changes based on positions with respect to edges of the monolithic scintillator.

9. The IEMR detection device of claim 1, wherein at least two retroreflectors are at least partially aligned with a respective photodetector of the array.

10. The IEMR detection device of claim 1, wherein the first side faces a source of the radiation.

11. A method of fabricating a monolithic scintillator for an ionizing electromagnetic radiation (IEMR) detector comprising:
forming a surface of a monolithic scintillator having a predetermined shaped pattern, the surface being on a first side of a monolithic scintillator, the predetermined shaped pattern providing a plurality of retroreflectors on the first side of the monolithic scintillator, where the second side is configured to be coupled to an array of photodetection devices for the TEMR detector.

12. The method of claim 11, wherein the predetermined shaped pattern of the surface is formed by cutting the monolithic scintillator to have a predetermined shape.

13. The method of claim 12, wherein the cutting comprises cutting grooves in the monolithic scintillator, the grooves comprise at least a first set of grooves and a second set of grooves, where the first set of grooves intersect the second set of grooves.

14. The method of claim 13, wherein the cutting further comprises cutting a third set of grooves, the third set of grooves intersecting the first set of grooves and the second set of grooves.

15. The method of claim 11, wherein the grooves have a V-shape.

16. The method of claim 11, further comprising coating an optical reflector on the plurality of retroreflectors.

17. The method of claim 11, wherein the predetermined shaped pattern of the surface is formed by printing the monolithic scintillator having the predetermined shaped pattern using a three-dimensional printer.

18. The method of claim 11, wherein the predetermined shaped pattern is formed by casting the monolithic scintillator having the predetermined shaped pattern using a mold.

19. The method of claim 18, further comprising providing the mold.

20. A method fabricating a detector for an ionizing electromagnetic radiation (IEMR) detector comprising:
obtaining a monolithic scintillator having a plurality of retroreflectors on a first side, the retroreflectors being formed as a predetermined shaped-pattern surface of the monolithic scintillator;
polishing a second side of the monolithic scintillator; and
coupling the second side of the monolithic scintillator to an array of photodetectors.

21. The method of claim 20, wherein the obtained monolithic scintillator has a reflective coated on the plurality of retroreflectors.

22. The method of claim 21, wherein the retroreflectors have a trihedral shape.
